(19) United States
(12) Patent Application Publication
(10) Pub. No.: US 2001/0005527 A1
(43) Pub. Date: Jun. 28, 2001

(54) THIN FILM FABRICATION

(76) Inventor: KATHLEEN MICHELLE VAETH, WEBSTER, NY (US)

Correspondence Address: SAM PASTERNACK, CHOATE, HALL & STEWART, 53 STATE STREET, BOSTON, MA, 02109, US

(21) Appl. No.: 08/829,005

(22) Filed: Mar. 31, 1997

(51) Int. Cl. C23C 16/00

(52) U.S. Cl. 427/248.1; 427/255.6

(57) ABSTRACT

A method of fabricating a thin film using chemical vapor deposition techniques is provided wherein a layered film is created by flowing a pyrolized monomer over a substrate maintained at a temperature less than 60° C. The pyrolized monomer condenses and polymerizes on the substrate and is subsequently heated in a low pressure, inert gas environment to convert the condensed precursor polymer to a PPV film.

### STATEMENT REGARDING FEDERALLY-SPONSORED RESEARCH

This invention was made with Government support under contract number N00014-95-1-0693 awarded by the Office of Naval Research. The Government has certain right in this invention.

### CROSS REFERENCE TO RELATED APPLICATIONS

Not Applicable.

### FIELD OF THE INVENTION

The present invention relates to a method of making a polymer film, and more particularly to a chemical vapor deposition process.

### BACKGROUND OF THE INVENTION

A light-emitting diode (LED) is a semiconductor device that converts electric energy into electromagnetic radiation, such as visible light. Commercially available devices, for example, emit red, orange, yellow, or green light. Light-emitting diodes are widely used for displays and indicators because, among other advantages, they are small and rugged, and because they have a low operating temperature and long life.

A traditional LED may, typically include a substrate made of gallium arsenide (GaAs), 250-350 micrometers thick. Both p- and n-type layers may be formed over the substrate by vapor deposition of a semiconductor material to provide the light emitting or active element. More recently however, electrouminescent (EL) polymers have shown promise for use as the active element in both LEDs and lasers since polymers have advantages in processing and formation of strong, flexible, light weight structures. Some of the most attractive candidates for polymer-based LEDs are those derived from poly(p-phenylene vinylene) (PPV).

Thin films of PPV can be fabricated by solution processing methods that in some cases include hazardous solvents, or by chemical vapor deposition (CVD) that does not include solvents. Of the two techniques, the solution-based method is more highly developed, and single layer PPV LEDs have been demonstrated with turn-on voltages as low as 2 volts. However, not only do the solvents used in the solution-based approach present environmental problems, the can cause undesirable side reactions that lead to carbonyl defects which quench EL emission from the polymer film.

The CVD method on the other hand offers a flexible and clean approach to film fabrication that is compatible with existing technology used for organic dye and inorganic semiconductor devices. However, single-layer PPV device turn-on voltages below 50 volts have not been demonstrated. These relatively high turn-on voltages have been attributed to the thick PPV layer that must be built up with the CVD method at typical substrate deposition temperatures 65° C., in order to avoid device shorting due to creation of pinholes in the film.

It would therefore be desirable to provide a single layer PPV LED which has a relatively low turn-on voltage and which is fabricated using CVD. It would also be desirable to provide a CVD method which can be used to fabricate a relatively thin layer of PPV having few or no holes therein.

### SUMMARY OF THE INVENTION

The present invention overcomes the disadvantages of known fabrication techniques by providing a chemical vapor deposition method that is particularly well suited to forming a polymer film that has a turn-on voltage of less than 5 volts, and preferably less than 4.5 volts, and even more preferably less than 4 volts.

In an exemplary method, a layered film is created by flowing a pyrolized monomer over a substrate maintained at a temperature less than 60° C. This unique reaction environment results in substantially uniform film coverage on the deposition surface and few or no pinholes. The pyrolized monomer condenses and polymerizes on the substrate and is subsequently heated in a low pressure, inert gas environment to convert the condensed precursor polymer to a PPV film.

### BRIEF DESCRIPTION OF THE DRAWINGS

A more complete understanding of the present invention and the attendant advantages and features thereof will be more readily understood by reference to the following detailed description when it is considered in conjunction with the accompanying drawings, wherein:

FIG. 1 is a schematic view of process apparatus in accordance with the invention;

FIG. 2 is an cross-sectional view of an exemplary polymer film device made in accordance with the invention;

FIG. 3 is a graph of the electrical performance and light output of a polymer film device made in accordance with the invention; and

FIG. 4 is a graph depicting the photoluminescence and electroluminescence spectra for a polymer film device of the invention.

### DETAILED DESCRIPTION OF THE INVENTION

The following description begins with a discussion of process apparatus components used to perform a method in accordance with the present invention, followed by a description of the inventive method and a polymer film formed in accordance therewith. Various monomers suitable for making the polymer film are presented, and the description concludes with discussion of an exemplary thin film PPV LED and the electrical characteristics thereof.

FIG. 1 is a schematic view of process apparatus or reactor that is useful for fabricating a thin film in accordance with the invention. The process apparatus includes a plenum 10 capable of containing a pressurized carrier gas, a mass flow controller 12, a reservoir 14 for a monomer, a pyrolizing furnace 16, a cold trap 18, a deposition zone 20, a vacuum furnace 22, and a vacuum or roughing pump 24. Fluid-tight passages connect the above components and create a gas flow path through the process apparatus. A barometric pressure gauge 26 and other instruments (not shown) can be provided to monitor system performance.

Although each of the described process apparatus components are known to those skilled in the art of chemical vapor deposition, a brief description of their functions follows. The roughing pump 24, for example, is provided to establish an extremely low pressure within the fluid-tight system. Specific operating pressure in the process apparatus, however, is establishing by the mass flow controller 12 which regulates the introduction of a carrier gas into the process apparatus. A suitable mass flow controller 12 is a conductance flowmeter manufactured by UNIT, Inc. The monomer reservoir 14 is a non-reactive vessel, such as a glass tube, capable of being heated to a temperature sufficient to cause a monomer to sublime into a vapor phase. Heat sufficient to pyrolize a monomer is provided by the pyrolizing furnace 16. Suitable furnaces, such as a tube furnace manufactured by Lindberg, Inc., are capable of obtaining pyrolizing temperatures of 500° C. to 1000° C. The cold trap 18 is a structure that prevents unreacted monomer exiting the furnace from passing to the deposition zone 20. The deposition zone 20 includes a support structure 28 capable of maintaining a substrate at a selected orientation within the path of pyrolized monomer. Finally, the vacuum furnace 22 provides the reactive conditions necessary to convert a precursor polymer to an electroluminescent polymer.

Having provided an overview of the process apparatus, operation thereof is more fully described in association with the following description of a method in accordance with the invention. In exemplary methods, a pressure is established between 0.001 to 5 torr, with a preferred range of 0.01 to 0.2 torr, and a carrier gas, such as nitrogen or argon, is introduced into the process apparatus. Preferably, the carrier gas has less than 2 ppm water and oxygen. The mass flow controller 12 is adjusted to establish a flow rate of the carrier gas at 0 sccm to 20 sccm, with a preferred range of 0 sccm to 10 sccm.

A monomer, heated to a temperature to place it in a vapor state, is then introduced into the carrier gas. For an exemplary monomer described below, a temperature in the range of 50° C. to 70° C. places the monomer in a vapor state. The monomer laden carrier gas flows into the furnace 16 at 600° C. to 700° C., with a preferred temperature of 625° C., wherein the monomer is pyrolized to a reactive monomer. The heated gas and reactive monomer exiting the furnace 16 can then be directed through a cold trap 18 to remove unpyrolized monomer from the heated gas stream. The cold trap 18 is not necessary as long as the gas flow rate and the distance between the deposition zone 20 and the furnace 16 preclude deposition of unpyrolized monomer on a substrate. However, because it is critical to exclude unpyrolized monomer, a cold trap 18 is preferred.

Although the process can include a carrier gas, other embodiments of the method do not require a carrier gas. For example, the monomer vapor can merely diffuse through the process apparatus or it can be pumped through the system at a low pressure such as less than 2 torr.

Either directly from the furnace 16, or by way of a cold trap 18, the heated gas carrying the reactive monomer is directed to the deposition zone 20 and a substrate 30, such as glass, positioned on the support structure 28. Significantly, the deposition zone 20 and/or the support structure 28 are maintained at a temperature lower than 60° C., preferably lower than 50° C., and even more preferably 20° C. to 28° C., and the reactive monomer condenses on the cool substrate 30 where it polymerizes in what is known as a condensation polymerization reaction. The above temperatures have significance in that they represent temperatures at which a coherent polymer film is formed instead of separate “islands” of film that are formed at higher temperatures, such as above 60° C. Although a coherent film is formed below 60° C., the number and size of defects decreases as the temperature is lowered to the temperature range of 20° C. to 28° C.

In a subsequent process step, the substrate covered with condensed monomer is moved to a vacuum furnace 22, wherein the monomer is converted to PPV. The vacuum oven 22 contains an inert atmosphere at a pressure of 1×10⁻⁶ to 2 torr and a temperature of 90° C. to 350° C., and in a preferred embodiment the conversion takes place at 1×10⁻⁶ to 0.1 torr in an inert atmosphere at 150° C. to 250° C. The substrate 30, now covered with a thin PPV film is removed from the vacuum furnace 22 and allowed to cool to room temperature in a vacuum atmosphere.

The following is an exemplary reaction that yields a PPV film under the above-described reaction conditions:

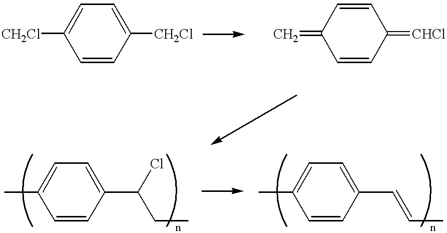

The unpyrolized monomer is dichloro-p-xylene, but other leaving groups can be substituted for chlorine, such as bromine. The pyrolized monomer which leads to the polymerization is chlorinated xylylene. Other possible polymers based on poly(p-phenylene vinylene) that can yield favorable results are as follows:

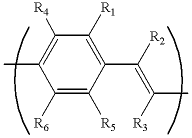

where R₁, R₄, R₅, R₆ may be selected from: hydrocarbon groups, methoxy, cyano, phenyl, alkoxy, amine, and halide such as Cl, Br, F, and I. R₂ and R₃ can include hydrocarbon groups, methoxy, cyano, phenyl, alkoxy, and amine. Were R₂ and R₃ to include halides, the reaction would yield poly phenylene acetylene.

In yet another example, the reaction is as follows:

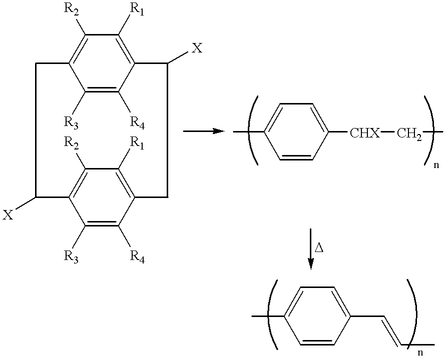

where R₁ and R₄ include: hydrocarbon groups, methoxy, cyano, phenyl, alkoxy, amine, and halide such as Cl, Br, F, and I; and R₂ and R₃ can include hydrocarbon groups, methoxy, cyano, phenyl, alkoxy, and amine.

There is no limit to the thickness of PPV film that can be built-up using the above-described inventive method, however, typical film thickness below 2000 Å, preferably in the range of 500 Å to 1000 Å are readily obtained. Thus, as used herein, a “thin” film is deemed to be less than 2,000 Å.

Metal electrodes are deposited on the thin PPV film by thermal evaporation, as is known in the art, to provide a thin film LED. An exemplary LED includes electrodes of Aluminum, Calcium or a Magnesium/Silver alloy, having a thickness of about 1,000 Å.

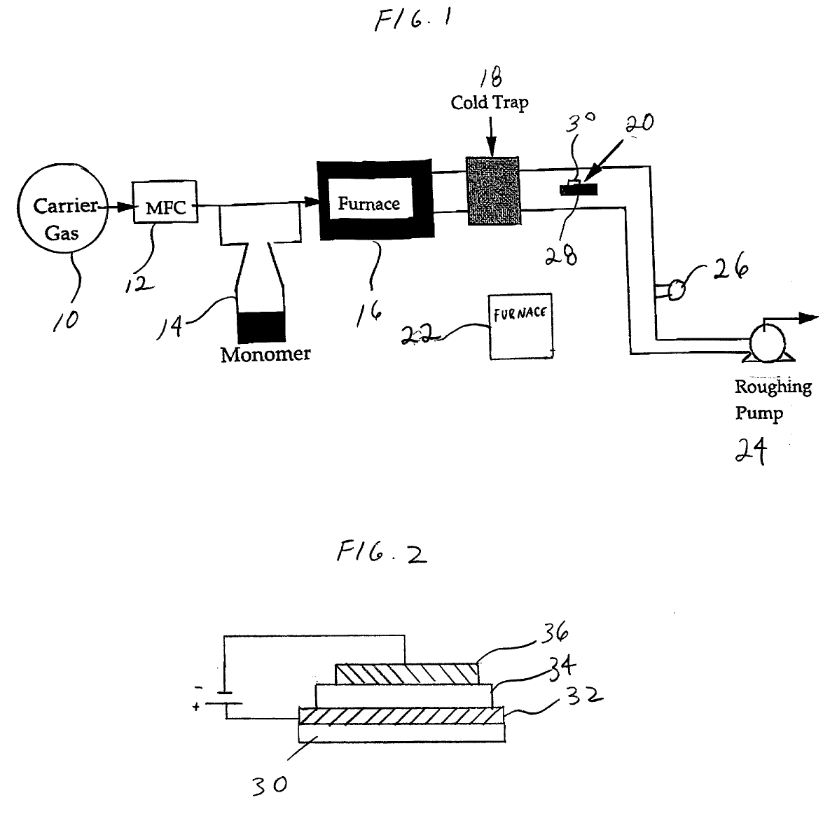

FIG. 2 is a representation of an exemplary thin film PPV LED that includes a glass substrate 30 coated with a layer 32 of an indium-tin oxide to which a PPV layer 34 having a thickness of 1,000 Å has been deposited. A layer 36 of aluminum covers the PPV layer 34. The exemplary LED has an active area of 4 mm², yet has one or less pinhole defects.

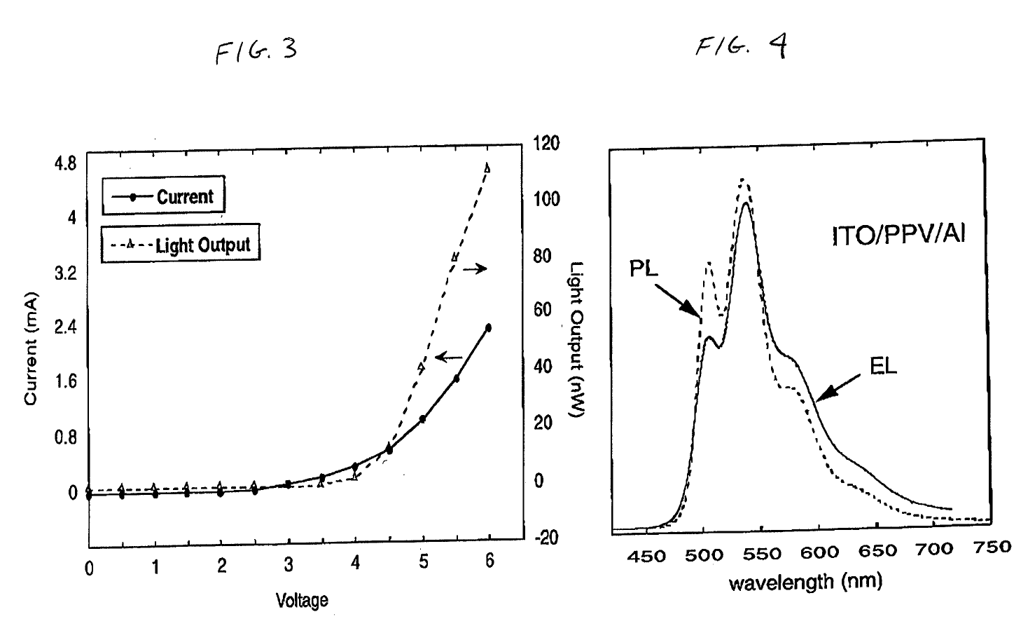

FIG. 3 is a graph of current-voltage and light-voltage performance for a single layer PPV LED made in the above-described manner. From the graph it is evident that above about 4 volts, the light output increases much faster than the current as voltage increases. Thus, 4 volts represents the “turn-on” voltage.

FIG. 4 is a plot of light output and wavelength for the PPV LED of the invention. The photoluminescence spectra is represented as a dashed line, and the electroluminescence is represented as a solid line. It should be noted that the light output can be easily seen by the human eye, even in a well-lit room.

Although the invention has been shown and described with respect to exemplary embodiments thereof, various other changes, omissions and additions in form and detain thereof may be made without departing from the spirit and scope of the invention. For example, the inventive method can be used to form films of other materials, such as poly(2,5 thienylene vinylene), and although an application of the film in an LED has been disclosed, there are other applications that can benefit from a thin polymer film.

What is claimed is:

1. A method of making a making a layered film structure comprising the steps of:
providing a monomer in a vapor state;
pyrolizing the monomer to provide a reactive monomer; and
exposing the reactive monomer to a substrate maintained at a temperature less than 60° C.

2. The method of claim 1, further comprising the step of establishing an inert gas environment have a pressure in the range of 0.001 torr to 5 torr.

3. The method of claim 2, wherein the inert gas is one of nitrogen and argon.

4. The method of claim 2, wherein the inert gas environment defines a gas flow path having a flow rate in the range of 0 sccm to 20 sccm.

5. The method of claim 1, wherein the step of pyrolizing the monomer includes the step of heating the monomer to a temperature in the rage of 500° C. to 1000° C. to provide a heated, reactive monomer.

6. The method of claim 5, further comprising the step of directing the heated, reactive monomer through a cold trap to remove unpyrolized monomer.

7. The method of claim 5, further comprising the step of directing the heated, reactive monomer to a deposition zone maintained at a temperature in the range of 20° C. to 28° C., wherein the reactive monomer condenses on the substrate and polymerizes to provide a coated substrate.

8. The method of claim 7, further comprising the step of heating the coated substrate to a temperature in the range of 90° C. to 350° C. in an inert atmosphere at a pressure in the range of 1×10⁻⁶ torr to 2 torr.

9. The method of claim 8, further comprising the step of cooling the coated substrate to room temperature in a vacuum environment after the step of heating the coated substrate.

10. The method of claim 1, wherein the monomer is dichloro-p-xylene.

11. A method of making a making a single layer film comprising the steps of:
establishing an inert gas environment have a pressure in the range of 0.001 torr to 5 torr;
causing the inert gas to flow at a rate in the range of 0 sccm to 20 sccm;
providing a monomer in a vapor state;
introducing the monomer in a vapor state into the flowing inert gas;
heating the flowing gas and the monomer to a temperature in the rage of 500° C. to 1000° C. to provide a gas flow including a pyrolized monomer;
directing the gas flow through a cold trap to remove unpyrolized monomer from the gas flow;
directing the gas flow including a pyrolized monomer to a deposition zone maintained at a temperature in the range of 20° C. to 28° C., wherein the pyrolized monomer condenses on the substrate and polymerizes to provide a coated substrate;
heating the coated substrate to a temperature in the range of 90° C. to 350° C. in an inert atmosphere at a pressure in the range of 1×10⁻⁶ torr to 2 torr; and
cooling the coated substrate to room temperature in a vacuum environment.

12. The method of claim 11, wherein the monomer is dichloro-p-xylene.

13. The method of claim 11, wherein the step of directing the gas flow including a pyrolized monomer includes the step of creating a precursor polymer coating less than 2000 Å thick on the substrate.

14. The method of claim 11, wherein the step of directing the gas flow including a pyrolized monomer includes the step of creating a precursor polymer coating than between 500 Å and 1000 Å thick on the substrate.

15. A method of making a making a PPV LED having a turn-on voltage under 5 volts comprising the steps of:
providing a glass substrate;
coating the glass substrate with a layer of indium-tin oxide;
coating the layer of indium-tin oxide with a PPV film by the steps of
providing a monomer in a vapor state,
pyrolizing the monomer to provide a reactive monomer, and
exposing the reactive monomer to the indium-tin oxide coated glass substrate at a temperature less than 60° C.; and
coating the PPV film with aluminum.

16. The method of claim 15, wherein the PPV film is between 500 Å and 1000 Å thick.
